(19) United States
(12) Patent Application Publication
(10) Pub. No.: US 2026/0362591 A1
(43) Pub. Date: Nov. 12, 2026

(54) ELECTRONIC COMPONENT STICKERS AND METHODS OF USE

(71) Applicant: ELECTRONINKS WRITEABLES, INC., Austin, TX (US)

(72) Inventor: S. Brett WALKER, Austin, TX (US)

(73) Assignee: ELECTRONINKS WRITEABLES, INC., Austin, TX (US)

(21) Appl. No.: 19/125,012

(22) PCT Filed: Oct. 27, 2023
(86) PCT No.: PCT/US2023/078102

§ 371 Date: Apr. 28, 2025

Related U.S. Application Data
(60) Provisional application No. 63/381,510, filed on Oct. 28, 2022.

(51) Int. Cl. H05K 1/02; H05K 1/189

(52) U.S. Cl. CPC H05K 1/0292; H05K 1/189; H05K 2201/0154; H05K 2201/10053; H05K 2201/10106; H05K 2201/10151

(57) ABSTRACT

Electronic stickers comprising at least one electronic component and conductive pads in electrical contact with the electronic component are provided. The electronic components are associated with a first side of the sticker, and an adhesive element is associated with a second side of the sticker. In some cases, at least one of the conductive pads has a foldable portion, so that the sticker can be electrically connected to a conductive trace on a non-conductive substrate by folding the conductive pad under the sticker and adhering the sticker to the nonconductive substrate so that the folded portion of the conductive pad contacts the conductive trace. In some cases, the conductive pad is configured to promote contact with a conductive ink, for example by configuring the conductive pad to have a serrated edge.

### CROSS-REFERENCE TO RELATED APPLICATIONS

This application claims the benefit of U.S. Provisional Application No. 63/381,510, filed on Oct. 28, 2022, the disclosure of which is incorporated herein by reference in its entirety.

### FIELD OF THE INVENTION

The present disclosure relates generally to novel stickers comprising electronic components and methods for their use. The stickers can be used to design and prepare inexpensive, decorative, creative, and highly flexible electronic circuits.

### BACKGROUND OF THE INVENTION

Modern electronic devices are typically manufactured from individual electronic components by physical assembly and electrical connection of the various components to achieve the desired electronic circuit behavior in a controlled manner. Such devices typically include one or more printed circuit boards (PCBs) that can include a laminated sandwich structure of conductive and insulating layers, where each conductive layer can be designed with particular traces, planes, and other features. The conductive layers are generally etched from one or more layers of copper material laminated onto and/or between counterpart layers of a non-conductive material. The desired electrical components can be attached to conductive pads on the outer layers of a PCB in shapes designed to accept the electrical connectors of each component. This attachment, which is generally a soldered attachment, provides both an electrical and a mechanical connection to the surface of the PCB. On multilayer boards, connections between conductive layers can be achieved through vias, which are small holes in the layers that can be filled with copper, or another suitable conducive material, to provide the electrical connection.

Simpler methods of preparing electrical circuits, either for the purpose of rapid testing of electrical circuit design or for the purpose of training, education, and creative use, have been described. For example, U.S. Pat. No. 9,297,523 B2 discloses conductive stickers containing light emitting diodes (LEDs). Such stickers require the use of an expensive conductive adhesive material, however, and require the careful placement of the stickers on pre-formed conductive traces in order to achieve proper electrical connections.

A need therefore exists for novel electronic stickers that are reliable, adaptable, easy to use and understand, and inexpensive.

### SUMMARY OF THE INVENTION

The instant disclosure addresses these and other considerations by providing novel electronic stickers and their methods of use.

In some aspects, the techniques described herein relate to an electronic sticker including: a non-conductive sticker substrate having a first side and a second side; a first electronic component physically associated with the first side of the non-conductive sticker substrate; a plurality of conductive pads physically associated with the first side of the non-conductive sticker substrate, wherein the plurality of conductive pads are in electrical contact with the first electronic component; and an adhesive element physically associated with the second side of the non-conductive sticker substrate, wherein at least one conductive pad has a foldable portion.

In some aspects, the techniques described herein relate to an electronic sticker including: a non-conductive sticker substrate having a first side and a second side; a first electronic component physically associated with the first side of the non-conductive sticker substrate; a plurality of conductive pads physically associated with the first side of the non-conductive sticker substrate, wherein the plurality of conductive pads are in electrical contact with the first electronic component; and an adhesive element physically associated with the second side of the non-conductive sticker substrate; wherein at least one conductive pad is configured to promote contact with a conductive ink.

### BRIEF DESCRIPTION OF THE DRAWINGS

FIG. 1 shows the top view of a sheet of electronic stickers having components with various electronic functionality.

FIGS. 2A and 2B show two electronic circuits that were created by placing electronic stickers with various electronic functionality on the surface of a non-conductive substrate. The electronic stickers were then connected to one another using a conductive ink drawn between conductive pads on the stickers.

FIG. 3A shows the top view of an electronic sticker containing an RGB LED, where the conductive pads associated with the common cathode connector and the red LED connector are folded under the sticker.

FIG. 3B shows the bottom view of the electronic sticker of FIG. 3A. The conductive pads that are folded under the sticker can be seen in this view.

### DETAILED DESCRIPTION OF THE INVENTION

It remains a challenge to make electronic components for use in prototyping circuits on paper or other non-conductive substrates. This is true, in particular, for components that are used in educational and artistic contexts. For these uses, it is important that the components be both easy to use and understand and also be inexpensive. Currently available examples of electronic components useful for these purposes include those using magnetic modules with a steel backing on a paper substrate and those comprising an adhesive layer that includes extremely expensive anisotropic conductive adhesives (also known as “z-axis” adhesives). In addition, each of these examples requires that a user preplan the dimensions and location of contacts on a prototype circuit before the conductive traces are prepared and before the electronic components are attached to the substrate.

In the electronic stickers of the instant disclosure, a pressure-sensitive adhesive that is non-conductive can be utilized in order to save on costs, specifically by fabricating the stickers with all of the conductive components either within the layers of a laminated substrate (e.g., a flexible PCB) or on the side of the sticker opposite the side of the sticker that carries the adhesive. In addition, unlike prior art electronic stickers, which were limited to stickers comprising LEDs, an entire ecosystem of electronic components and sub-circuits can be created using the unique features of the disclosed stickers. Specifically, the disclosed electronic components and sub-circuits can include transistors, batteries, LEDs, and other items such as buttons and speakers at very low cost and with low profile. The disclosed stickers are simple to understand and extremely easy to use.

As will also be disclosed herein, and unlike prior art modular electronic systems, where electrical connectors need to be laid out on a non-conductive substrate at precise locations prior to attachment of the electronic stickers to the substrate, a user can simply place the disclosed stickers on a paper substrate, or other suitable non-conductive substrate, and then draw electrical connections between conductive pads on the same or on other electronic stickers using conductive ink or conductive tape. If a user prefers to use electrical connectors that are already in place on the substrate, the conductive pads on the disclosed electronic stickers can be folded under the sticker prior to their attachment. The conductive pad is then electrically accessible from the bottom of the sticker, where it can make contact with a preexisting connector on the substrate. Connections can also be made between multiple stickers by folding one or more conductive pads under a sticker and then contacting the folded pad with a conductive pad (folded or unfolded) on a second sticker.

The lack of a need for an expensive conductive adhesive on the sticker, and the ability for the user to draw conductive lines between stickers after the stickers have been affixed to a non-conductive substrate provide significant advantages for this system, both in the ease of use as well as cost, compared to traditional electronic stickers.

Accordingly, the instant disclosure provides in one aspect electronic stickers comprising a non-conductive sticker substrate having a first side and a second side; a first electronic component physically associated with the first side of the non-conductive sticker substrate; a plurality of conductive pads physically associated with the first side of the non-conductive sticker substrate; and a non-conductive adhesive element physically associated with the second side of the non-conductive sticker substrate.

The sticker substrate used in the instant electronic sticker can be any suitable non-conductive substrate. As is understood by those of ordinary skill in the art, the sticker substrate, or at least some layers of a laminated sticker substrate, should be non-conductive, so that the various electronic features of the electronic stickers are electrically isolated from one another. Suitable sticker substrates include, without limitation, any suitable dielectric material that is typically used in the manufacture of PCBs. Such composites can contain a matrix (e.g., an epoxy resin) and a reinforcement (e.g., a woven material, a nonwoven material, a glass fiber, and even paper), and in some cases the sticker substrate can contain a filler (e.g., to increase the dielectric constant of the material).

The sticker substrate is preferably a flexible material, so that conductive pads physically associated with the sticker substrate are freely foldable. In some embodiments, the sticker substrate is a polyimide foil, for example Kapton or UPILEX material. Such materials are typically used for flexible printed circuits, in particular in small form-factor consumer electronics, or for flexible interconnects. Such materials are advantageously resistant to high temperatures. In some embodiments, the sticker substrate is a polyimide-fluoropolymer composite foil, for example Pyralux.

The term “non-conductive” should not be understood to require that any so-described material has no conductivity, only that the material is sufficiently non-conductive to provide a suitable practical utility for the stated purpose.

The sticker substrate of the instant electronic stickers is understood to have a first side and a second side that are electrically isolated from one another. In other words, absent a via, or other such electrical connector between the two sides of the sticker substrate, electrical current does not flow from one side of the sticker to the other.

As noted above, the electronic sticker also includes at least a first electronic component that is physically associated with the first side of the non-conductive sticker substrate. The electronic component can be any component that has a functionality desired by the user in a possible electrical circuit design. Exemplary electronic components include, without limitation, those components recited above, for example, a transistor, a battery, an LED, a button, a switch, a speaker, and the like.

As also noted above, the electronic sticker also includes a plurality of conductive pads physically associated with the first side of the non-conductive sticker substrate. The conductive pads are preferably fabricated from metal and are physically associated with the first side of the non-conductive sticker substrate by any suitable method or material, as would be understood by those of ordinary skill in the art.

In some embodiments, the metal used to fabricate the conductive pads can be gold, silver, copper, indium, palladium, aluminum, iron, cobalt, nickel, an alloy thereof, an oxide thereof, or a mixture thereof. In preferred embodiments, the metal used to fabricate the conductive pads can be gold, silver, copper, an alloy thereof, an oxide thereof, or a mixture thereof. In more preferred embodiments, the metal used to fabricate the conductive pads can be silver, an alloy thereof, an oxide thereof, or a mixture thereof.

The conductive pads of the instant electronic stickers are in electrical contact with the first electronic component. This electrical contact can be provided by any suitable electrical conductor. The electrical conductor between the conductive pads and the first electronic component is preferably shielded from electrical exposure to either the first side or the second of the sticker substrate, for example, by lamination within a layer of a PCB or through another suitable insulating material. The conductor can be, for example, a metallic conductor between the conductive pads and the first electronic component.

In some embodiments, at least one conductive pad has a foldable portion. Such a foldable portion enables electrical contact of the electronic components of the electronic sticker with either or both of the first side and/or the second side of the non-conductive sticker substrate, where the first electronic component is physically associated with the first side of the non-conductive sticker substrate, and the non-conductive adhesive element is physically associated with the second side of the non-conductive sticker substrate.

In more specific embodiments, placing the conductive pad in the first position allows electrical contact of the conductive pad from the first side of the electronic sticker.

In other more specific embodiments, placing the conductive pad in the second position allows electrical contact of the conductive pad from the second side of the electronic sticker.

In some embodiments, at least one conductive pad is configured to promote contact with a conductive ink. Such a configuration can, for example, be a serrated configuration, where a serrated edge on the conductive pad provides an enlarged surface area for contact with a conductive ink as a user draws contacts between two or more electronic stickers on a non-conductive substrate as a circuit is being formed.

In another aspect, the disclosure provides methods of using electronic stickers. These methods include the steps of placing one or more of the above-described electronic stickers on a non-conductive substrate and contacting at least one conductive pad on the one or more electronic stickers with a conductive ink. In some embodiments, two or more of the above-described electronic stickers are placed on the non-conductive substrate. More specifically, the two or more electronic stickers are electrically connected using the conductive ink. Any suitable conductive ink can be used in the practice of these methods, for example the conductive ink described in U.S. Pat. No. 10,703,924B2 , the disclosure of which is incorporated herein by reference for all purposes. Exemplary non-conductive substrates for use in these methods include paper.

It will be readily apparent to one of ordinary skill in the relevant arts that other suitable modifications and adaptations to the electronic stickers and methods described herein may be made without departing from the scope of the invention or any embodiment thereof. Having now described the present invention in detail, the same will be more clearly understood by reference to the following Examples, which are included herewith for purposes of illustration only and are not intended to be limiting of the invention.

### EXAMPLES

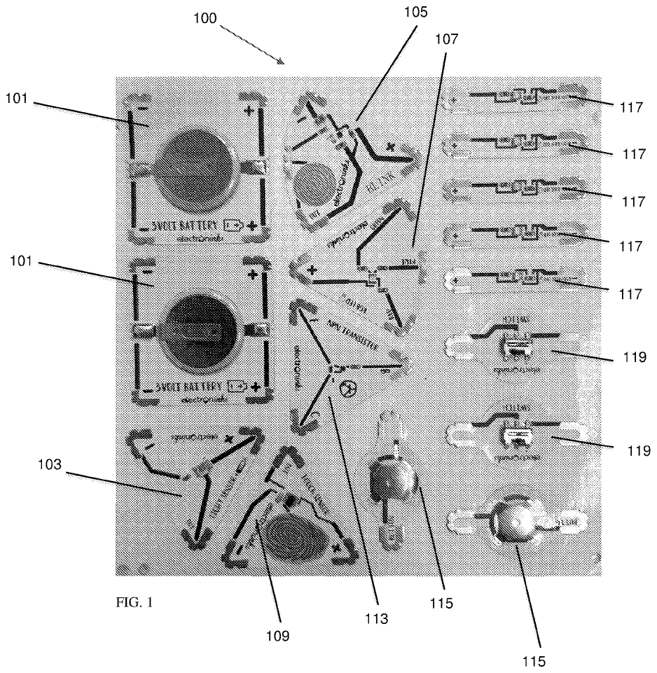

FIG. 1 shows a sheet of exemplary electronic stickers 100 that have been prepared on an inexpensive, laminated, adhesive, polyimide substrate with a removeable backing. The substrates are prepared using traditional printed circuit board (PCB) techniques. The outline of each sticker is cut through the PCB to the adhesive layer, without cutting the removable backing, so that each sticker can individually be removed from the sheet, thus exposing the adhesive on the bottom surface of the sticker. The PCB's themselves are made from traditional fabrication techniques such as etching of copper clad polymers or screen printed silver layers on polymer substrates.

Each sticker includes one or more electronic components that are electrically connected on the surface of the sticker to one another and to conductive traces within the PCB, to create electronic stickers with the desired electrical properties, as would be understood by those of ordinary skill in the art. Conductive traces within the PCB are indicated by dark lines on each sticker in FIG. 1. Conductive pads with serrated edges are mounted on the corners or ends of each sticker to provide contact points for conductive ink as the electronic stickers are electrically connected into circuits on a paper or other suitable non-conductive surface.

The exemplary stickers of FIG. 1 include stickers providing various electronic functionalities, including battery stickers 101, a light sensor sticker 103, a blink sticker 105, an RGB LED sticker 107, a touch sensor sticker 109, an NPN transistor sticker 113, button switch stickers 115, red/blue LED stickers 117, and rocker switch stickers 119. The polarity or other relevant electrical property of each conductive pad is printed on the surface of the sticker.

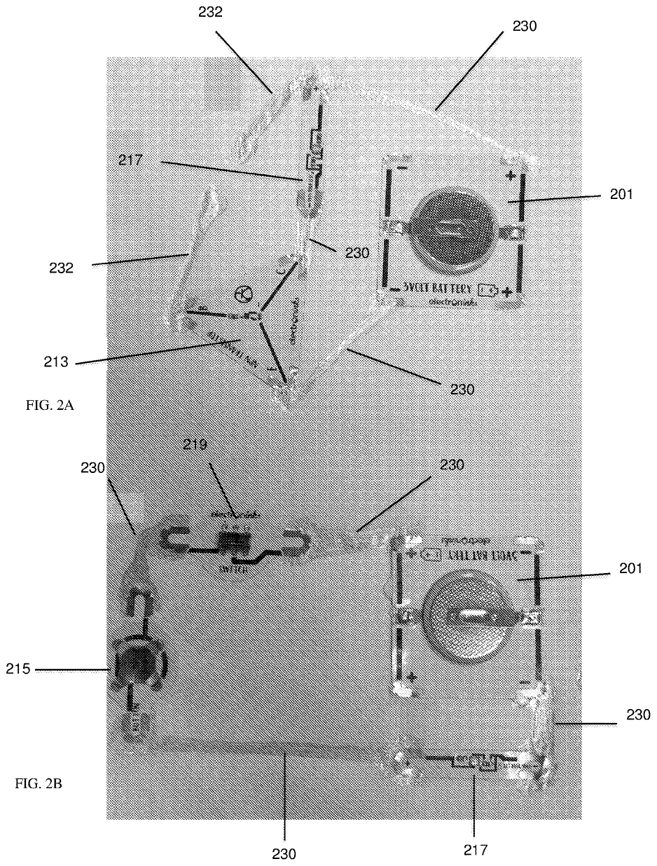

FIGS. 2A and 2B illustrate the use of the disclosed electronic stickers to create electronic circuits on a suitable non-conductive substrate, such as paper. These examples demonstrate the advantages of stickers that can be electrically connected to one another after they have been adhered to the non-conductive substrate.

In FIG. 2A, a battery sticker 201 is connected to an NPN transistor sticker 213 and a red/blue LED sticker 217 through conductive traces 230 drawn using conductive ink between the serrated conductive pads of each sticker. Open-ended conductive traces 232 are drawn from the NPN transistor sticker 213 and the red/blue LED sticker 217.

In FIG. 2B, a battery sticker 201 is connected through both a button switch sticker 215 and a rocker switch sticker 219 to a red/blue LED sticker 217. The circuit is created by drawing conductive traces 230 between serrated conductive pads on each of the electronic stickers using conductive ink after the stickers have been adhered to the paper substrate.

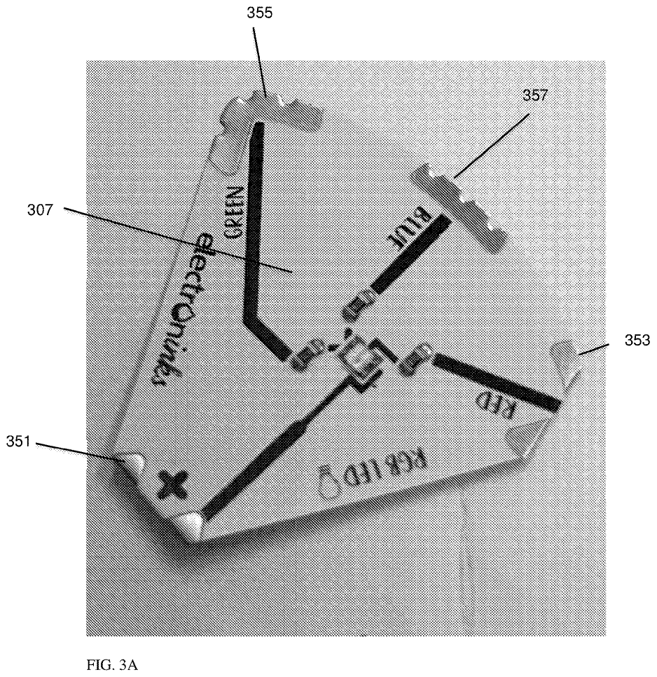

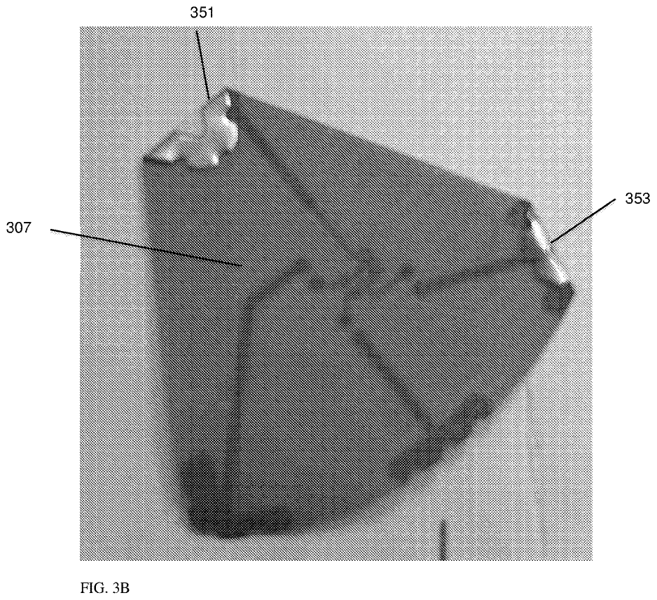

FIGS. 3A and 3B illustrate some of the advantages of foldable conductive pads in an exemplary electronic sticker. Specifically, FIG. 3A shows the top surface of an RGB LED sticker 307, where the conductive pads associated with the common cathode connector 351 and with the red LED connector 353 are folded under the sticker, whereas the conductive pads associated with the green LED connector 355 and the blue LED connector 357 remain unfolded. As is apparent in this view, the serrated edges of the green LED connector 355 and the blue LED connector 357 facilitate contact with conductive traces prepared using a conductive ink after the electronic sticker has been adhered to a paper substrate or another suitable non-conductive substrate.

FIG. 3B shows the bottom, adhesive surface of an RGB LED sticker 307, where the conductive pads associated with the common cathode connector 351 and with the red LED connector 353 are folded under the sticker and are therefore accessible for electrical connection with appropriately-spaced conductive contacts when the sticker is adhered to an otherwise non-conductive substrate. The conductive traces within the laminated PCB structure are visible in this view.

All patents, patent publications, and other published references mentioned herein are hereby incorporated by reference in their entireties as if each had been individually and specifically incorporated by reference herein.

While specific examples have been provided, the above description is illustrative and not restrictive. Any one or more of the features of the previously described embodiments can be combined in any manner with one or more features of any other embodiments in the present invention. Furthermore, many variations of the invention will become apparent to those skilled in the art upon review of the specification. The scope of the invention should, therefore, be determined by reference to the appended claims, along with their full scope of equivalents.

1. An electronic sticker comprising:
a non-conductive sticker substrate having a first side and a second side;
a first electronic component physically associated with the first side of the non-conductive sticker substrate;
a plurality of conductive pads physically associated with the first side of the non-conductive sticker substrate, wherein the plurality of conductive pads are in electrical contact with the first electronic component; and
an adhesive element physically associated with the second side of the non-conductive sticker substrate;
wherein at least one conductive pad has a foldable portion.

2. The electronic sticker of claim 1, wherein the foldable portion of the at least one conductive pad can be placed in a first position or a second position.

3. The electronic sticker of claim 2, wherein the first position allows electrical contact of the at least one conductive pad from the first side of the electronic sticker.

4. The electronic sticker of claim 2, wherein the second position allows electrical contact of the at least one conductive pad from the second side of the electronic sticker.

5. The electronic sticker of claim 1, wherein at least one conductive pad is a conductive metal.

6. (canceled)

7. The electronic sticker of claim 1, wherein the non-conductive sticker substrate is a polyimide substrate.

8. The electronic sticker of claim 1, wherein the non-conductive sticker substrate is a laminated substrate.

9. (canceled)

10. The electronic sticker of claim 1, comprising a plurality of electronic components physically associated with the first side of the non-conductive sticker substrate, wherein the plurality of conductive pads are in electrical contact with the plurality of electronic components.

11. The electronic sticker of claim 1, wherein the adhesive element is non-conductive.

12. The electronic sticker of claim 1, wherein at least one conductive pad is configured to promote contact with a conductive ink.

13. (canceled)

14. An electronic sticker comprising:
a non-conductive sticker substrate having a first side and a second side;
a first electronic component physically associated with the first side of the non-conductive sticker substrate;
a plurality of conductive pads physically associated with the first side of the non-conductive sticker substrate, wherein the plurality of conductive pads are in electrical contact with the first electronic component; and
an adhesive element physically associated with the second side of the non-conductive sticker substrate;
wherein at least one conductive pad is configured to promote contact with a conductive ink.

15. The electronic sticker of claim 14, wherein the at least one conductive pad has a serrated edge.

16. The electronic sticker of claim 14, wherein at least one conductive pad has a foldable portion.

17. The electronic sticker of claim 16, wherein the foldable portion of the at least one conductive pad can be placed in a first position or a second position.

18. The electronic sticker of claim 17, wherein the first position allows electrical contact of the at least one conductive pad from the first side of the electronic sticker.

19. The electronic sticker of claim 17, wherein the second position allows electrical contact of the at least one conductive pad from the second side of the electronic sticker.

20. The electronic sticker of claim 14, wherein at least one conductive pad is a conductive metal.

21. (canceled)

22. The electronic sticker of claim 14, wherein the non-conductive sticker substrate is a polyimide substrate.

23. The electronic sticker of claim 14, wherein the non-conductive sticker substrate is a laminated substrate.

24. (canceled)

25. The electronic sticker of claim 14, comprising a plurality of electronic components physically associated with the first side of the non-conductive sticker substrate, wherein the plurality of conductive pads are in electrical contact with the plurality of electronic components.

26. (canceled)
